(19) United States
(12) Patent Application Publication
(10) Pub. No.: US 2023/0051621 A1
(43) Pub. Date: Feb. 16, 2023

(54) SEMICONDUCTOR STRUCTURE AND METHOD FOR MANUFACTURING THE SAME

(71) Applicant: MACRONIX INTERNATIONAL CO., LTD., Hsinchu (TW)

(72) Inventors: Ting-Feng LIAO, Hsinchu City (TW); Sheng-Hong CHEN, Kaohsiung City (TW); Kuang-Wen LIU, Hsinchu City (TW)

(21) Appl. No.: 17/400,189

(22) Filed: Aug. 12, 2021

(51) Int. Cl. H01L 27/11582; H01L 27/11556; H01L 27/11524; H01L 27/1157; H01L 29/66

(52) U.S. Cl. CPC H01L 27/11582; H01L 27/11556; H01L 27/11524; H01L 27/1157; H01L 29/6656

(57) ABSTRACT

A semiconductor structure and a method for manufacturing a semiconductor are provided. The semiconductor structure includes a channel pillar, a dielectric layer formed on the channel pillar, a via formed in the dielectric layer and electrically connected to the channel pillar, and a spacer formed between the dielectric layer and the via.

### BACKGROUND

### Technical Field

The present disclosure relates to a semiconductor structure and a method for manufacturing the same, and more particularly to a semiconductor structure including a spacer and a method for manufacturing the same.

### Description of the Related Art

Etching technology has been used widely in semiconductor manufacturing processes. For example, the etching process can be used to form a via on a channel pillar in order to form an ohmic contact between a pad of the channel pillar and the via. However, the etching process for forming the via may result in an over-etching problem. Such over-etching problem may lead to a leakage path in the semiconductor structure and affect the insulating property of wires in the semiconductor structure.

It is important to provide technology for a semiconductor structure and a method for manufacturing the same, which may prevent the leakage path from happening, maintain a well ohmic contact between the channel pillar and the via, and improve the electrical performance of the semiconductor structure.

### SUMMARY

The present disclosure relates to a semiconductor structure and a method for manufacturing the same.

According to an embodiment of the present disclosure, a method for manufacturing a semiconductor structure is provided. The method includes providing a channel pillar; forming a dielectric layer on the channel pillar; forming a spacer in the dielectric layer, and forming a via in the dielectric layer. The via is electrically connected to the channel pillar. The spacer is between the dielectric layer and the via.

According to another embodiment of the present disclosure, a semiconductor structure is provided. The semiconductor structure includes a channel pillar, a dielectric layer formed on the channel pillar, a via formed in the dielectric layer and electrically connected to the channel pillar and a spacer formed between the dielectric layer and the via.

The above and other embodiments of the disclosure will become better understood with regard to the following detailed description of the non-limiting embodiment(s). The following description is made with reference to the accompanying drawings.

### BRIEF DESCRIPTION OF THE DRAWINGS

FIGS. 1-5 illustrate a method for manufacturing a semiconductor structure according to an embodiment of the present disclosure.

### DETAILED DESCRIPTION

Various embodiments will be described more fully hereinafter with reference to accompanying drawings, which are provided for illustrative and explaining purposes rather than a limiting purpose. For clarity, the components may not be drawn to scale. In addition, some components and/or reference numerals may be omitted from some drawings. It is contemplated that the elements and features of one embodiment can be beneficially incorporated in another embodiment without further recitation.

The embodiments of the present disclosure could be implemented in various semiconductor structures in the applications. For example, the embodiments of the present disclosure could be applied to, but not limited to, a 3-dimensional memory device with vertical channels or a 3-dimensional integrated circuit (IC) structure with high aspect ratio.

Use of term “electrically connected” in the specification and claims may mean that elements form an ohmic contact, a connection between elements allows an electric current flowing through the elements, or an element operationally relates to another element. The term “operationally relates to” may mean that an element is configured to drive another element without an electric current flowing therebetween.

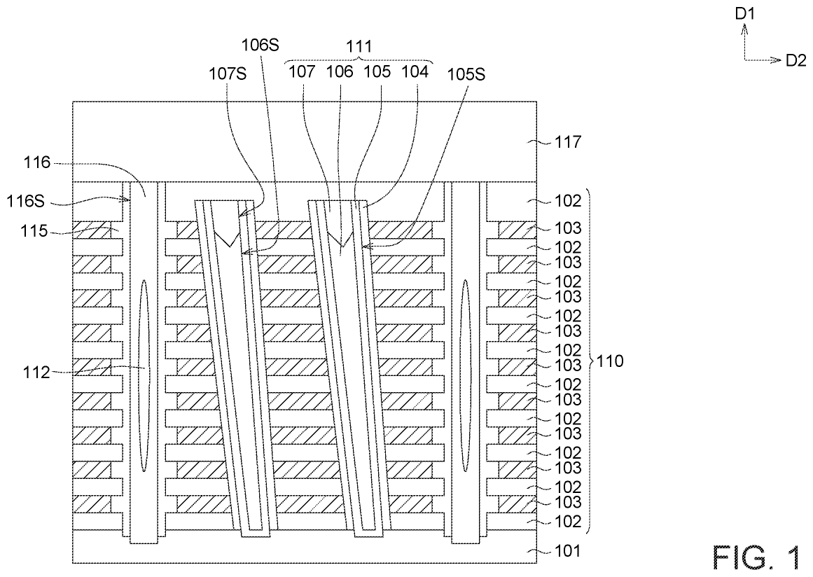

FIGS. 1-5 illustrate a method for manufacturing a semiconductor structure according to an embodiment of the present disclosure.

Referring to FIG. 1, a substrate 101 is provided. The substrate 101 may include a doped or undoped semiconductor material, such as P-type silicon (Si), N-type silicon or undoped silicon. The present disclosure is not limited thereto. In another embodiment, the substrate 101 may use other materials such as a dielectric material or a conductive material. The stacked structure 110 is formed on the substrate 101. The stacked structure 110 may include a plurality of insulating layers 102 and a plurality of conductive layers 103 stacked alternately along a first direction D1. The first direction D1 may be a normal direction to an upper surface of the substrate 101. The insulating layers 102 are separated from each other by the conductive layers 103. The insulating layer 102 may include insulating materials comprising an oxide. In an embodiment, the insulating layer 102 may include silicon oxide. The conductive layer 103 may include conductive materials, such as metal. In an embodiment, the conductive layer 103 may include tungsten.

The channel pillar 111 is provided in the stacked structure 110. In this embodiment, the channel pillar 111 is formed on the substrate 101 and passing through the stacked structure 110 along the first direction D1. The channel pillar 111 may include a memory layer 104, a channel layer 105, an insulating pillar 106 and a pad 107. The pad 107 may be formed on the insulating pillar 106. The channel layer 105 may be formed on a sidewall 106S of the insulating pillar 106 and a sidewall 107S of the pad 107. The memory layer 104 may be formed on a sidewall 105S of the channel layer 105. In this embodiment, the memory layer 104 may have a tubular shape and enclose the channel layer 105; the channel layer 105 may have a tubular shape and enclose the insulating pillar 106 and the pad 107; the channel layer 105 is disposed between the memory layer 104 and the insulating pillar 106 and/or the memory layer 104 and the pad 107.

The memory layer 104 may include a multilayer structure known from memory technologies as ONO (oxide-nitride-oxide), ONONO (oxide-nitride-oxide-nitride-oxide), ONONONO (oxide-nitride-oxide-nitride-oxide-nitride-oxide), SONOS (silicon-oxide-nitride-oxide-silicon), BE-SONOS (bandgap engineered silicon-oxide-nitride-oxide-silicon), TANOS (tantalum nitride, aluminum oxide, silicon nitride, silicon oxide, silicon), MA BE-SONOS (metal-high-k bandgap-engineered silicon-oxide-nitride-oxide-silicon), and combinations of those layers. The channel layer 105 may include a doped or undoped semiconductor material. In an embodiment, the channel layer 105 may include polysilicon, such as a doped polysilicon or an undoped polysilicon. The insulating pillar 106 may include insulating materials comprising an oxide. In an embodiment, the insulating pillar 106 may include silicon oxide. The pad 107 may include a semiconductor material, such as silicide, doped or undoped semiconductor material. In an embodiment, the pad 107 may be electrically connected to the channel layer 105.

In an embodiment, the conductive film 116 is provided in the stacked structure 110. The conductive film 116 is formed on the substrate 101 and passing through the stacked structure 110 along the first direction D1. A dielectric film 115 may be formed on a sidewall 116S of the conductive film 116 and disposed between the conductive film 116 and the stacked structure 101. In an embodiment, the conductive film 116 may include an air gap 112 formed in the conductive film 116. The conductive film 116 may include a conductive material, such as polysilicon, metal, or other suitable conductive materials. In an embodiment, the conductive film 116 may include tungsten. The dielectric film 115 may include dielectric material, such as silicon oxide. A dielectric layer 117 may then be formed on the stacked structure 110 and above the channel pillar 111 by a deposition process. The dielectric layer 117 may include oxide, such as silicon oxide.

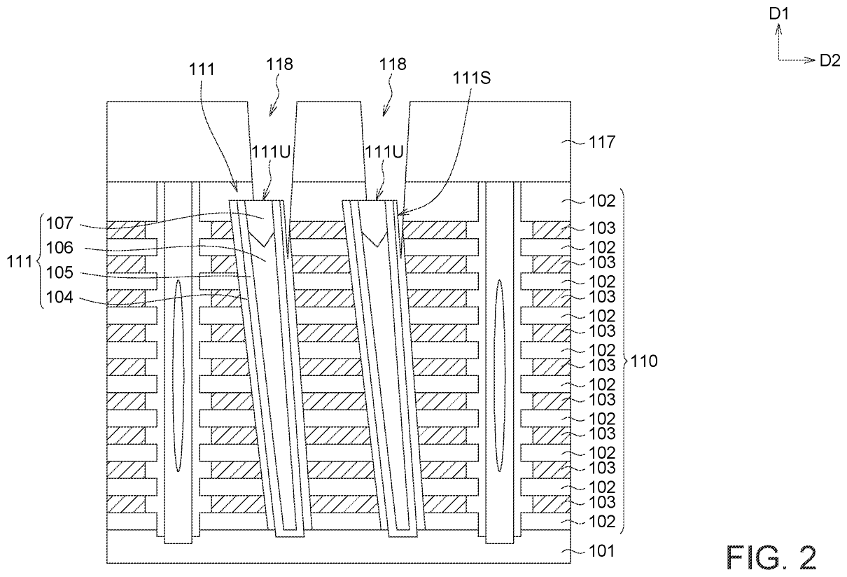

Referring to FIG. 2, openings 118 are formed in the dielectric layer 117. For example, the dielectric layer 117 may be patterned by a photolithography process so as to form the openings 118. The opening 118 extends downwardly in the first direction D1 and passes through the dielectric layer 117. The openings 118 extend to an insulating layer 102 at the top of the stacked structure 110 to expose upper surfaces 111U of the channel pillars 111 respectively. In an embodiment, the etching process in the photolithography process used to form the openings 118 may not be stopped at the upper surfaces 111U of the channel pillars 111; the etching process is continued to remove a portion of the memory layer 104 and make at least one conductive layer 103 in the stacked structure 110 be exposed in the openings 118 after the upper surfaces 111U of the channel pillars 111 are exposed. In this embodiment, as shown in FIG. 2, the upper surface 111U of the channel pillar 111, the sidewall 111S of the channel pillar 111 (or may be understood as the memory layer 104) and the sidewall of the uppermost conductive layer 103 among the conductive layers 103 are exposed in the opening 118.

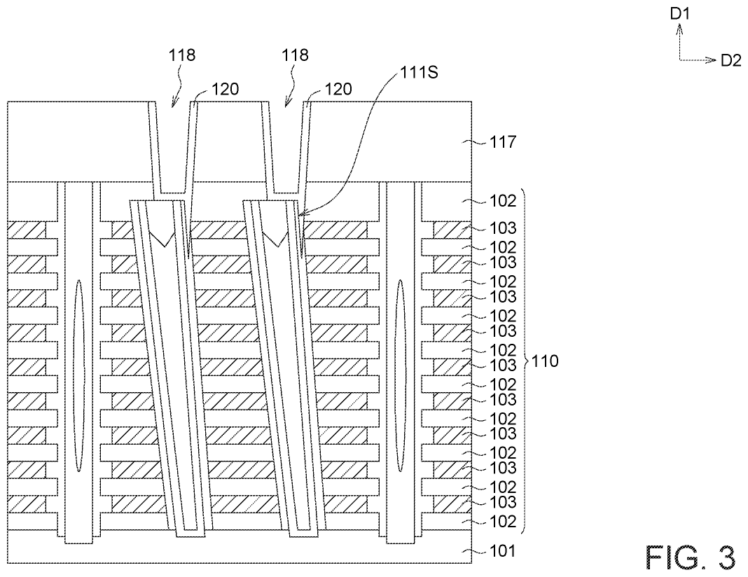

Referring to FIG. 3, spacers 120 are then formed in the dielectric layer 117. Specifically, the spacer 120 is formed on inner sidewall and bottom of the opening 118. The spacer 120 may be formed by a deposition process. The spacer 120 may include oxide, such as silicon oxide. In embodiments, the spacer 120 is not limited to the profile as shown in the figure. The spacer 120 may have any possible profile resulting from a deposition on the inner sidewall and bottom of the opening 118. For example, an upper surface of the spacer 120 may be a planar surface or a non-planar surface.

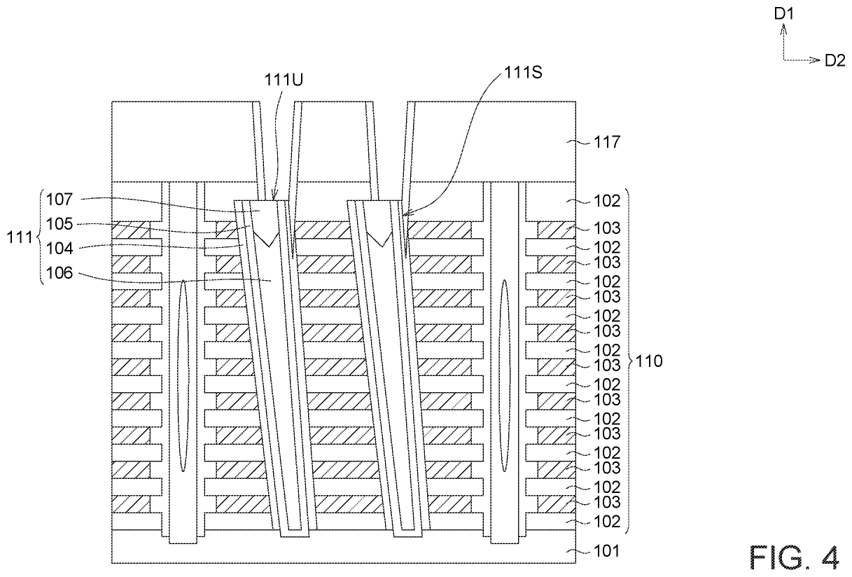

Referring to FIG. 4. Then, an anisotropic etching process may be used to remove a portion of the spacer 120 on the upper surface 111U of the channel pillar 111, remaining a portion of the spacer 120 on the inner sidewall of the opening 118. Specifically, a portion of the spacer 120 on the upper surface 111U of the channel pillar 111 is removed so as to expose the pad 107. In an embodiment, as shown in FIG. 4, a portion of the spacer 120 is disposed between the channel pillar 111 and the conductive layer 103 of the stacked structure 110 after the anisotropic etching process. In other words, a portion of the spacer 120 is formed on the sidewall 111S of the channel pillar 111.

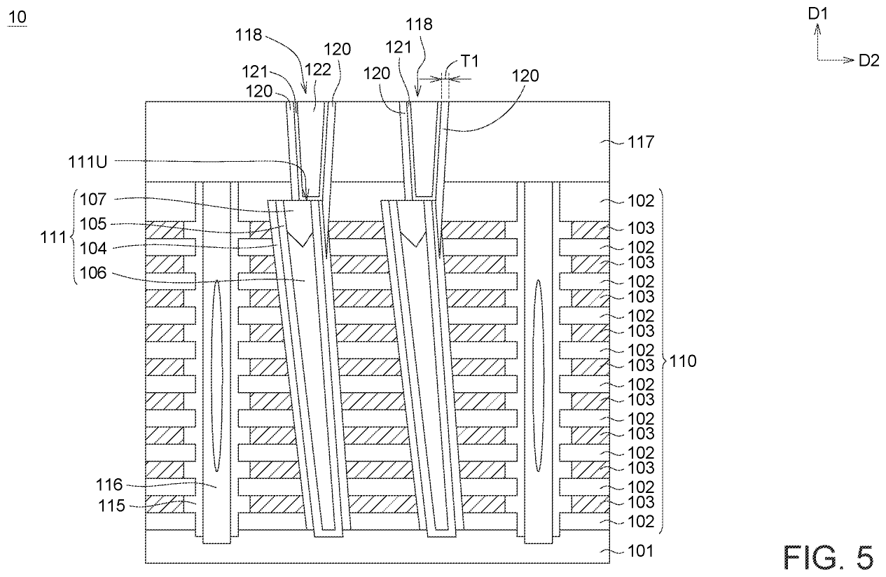

Referring to FIG. 5. Then, a barrier layer 121 may be formed on a sidewall of the spacer 120 and the upper surface 111U of the channel pillar 111. The barrier layer 121 may include a conductive material, such as metal. In an embodiment, the barrier layer 121 may include titanium (Ti) or titanium nitride (TiN). A via 122 may be formed on an inner sidewall of the barrier layer 121 to fill the opening 118 after the formation of the barrier layer 121. The via 122 may be formed by a deposition process. The via 122 may include a conductive material, such as metal. In an embodiment, the via 122 may include tungsten. The spacer 120 may be disposed between the dielectric layer 107 and the via 122. The barrier layer 121 may be disposed between the spacer 120 and the via 122. The via 122 may be electrically connected to the pad 107 of the channel pillar 111 through the barrier layer 121. In this embodiment, the barrier layer 121 directly contacts the pad 107 of the channel pillar 111. The present disclosure is not limited thereto.

Through performing the method shown in FIGS. 1-5, a semiconductor structure 10 is provided. As shown in FIG. 5, the semiconductor structure 10 includes the substrate 101, the stacked structure 110 on the substrate 101 and including a plurality of insulating layers 102 and a plurality of conductive layers 103 stacked alternately along the first direction D1, the channel pillar 111 passing through the stacked structure 110 along the first direction D1, the dielectric layer 117 formed above the channel pillar 111 and on the stacked structure 110, a via 122 formed in the dielectric layer 117 and electrically connected to the channel pillar 111, and a spacer 120 formed between the dielectric layer 117 and the via 122.

The spacer 120 may be used to separate the via 122 from the conductive layer 103 in the stacked structure 110. The spacer 120 may have a thickness T1 between 10-500 angstroms (Å) in a second direction D2 perpendicular to the first direction D1. Specifically, as shown in FIG. 5, a portion of the spacer 120 is formed between the channel pillar 111 and the conductive layer 103 exposed in the opening 118 (in this embodiment, the conductive layer 103 exposed in the opening 118 may be understood as the uppermost conductive layer 103 among the conductive layers 103) so as to prevent the via 122 from contacting the exposed conductive layer 103. Therefore, a leakage path between the via 122 and the exposed conductive layer 103 can be prevented. The spacer 120 may be used to electrically insulate the via 122 from the conductive layer 103 exposed in the opening 118.

In an embodiment, the thickness T1 of the spacer 120 in the second direction D2 may be 100 angstroms. When the thickness T1 of the spacer 120 in the second direction D2 is less than 10 angstroms, the insulation between the via 122 and the conductive layer 103 in the stacked structure 110 is insufficient to prevent the leakage path. When the thickness T1 of the spacer 120 in the second direction D2 is larger than 500 angstroms, the conductive path between the via 122 and the pad 107 may be blinded and a reliable conductive path cannot be established.

The semiconductor structure 10 may further include a barrier layer 121 between the via 122 and the spacer 120. The barrier layer 121 may be disposed on the sidewall of the via 122 and enclosing the via 122. The semiconductor structure 10 may further include a conductive film 116 passing through the stacked structure 110 along the first direction D1 and a dielectric film 115 between the conductive film 116 and the stacked structure 110. In this embodiment, two channel pillars 111 and two conductive films 116 are exemplary shown in the semiconductor structure 10; however, the present disclosure is not limited thereto. The semiconductor structure 10 may include more or less channel pillar(s) 111 and conductive film(s) 116.

In an embodiment, the semiconductor structure 10 could be applied to a 3-dimensional vertical-channel (VC) NAND memory device, and the semiconductor structure 10 may include memory cells defined in the memory layer 104. The memory cells may be defined in the memory layer 104 at intersections between the conductive layers 103 and the channel layers 105 of the channel pillar 111. The conductive layers 103 may be functioned as word lines (WL). The conductive films 116 may be functioned as common source lines (CSL). In an embodiment, the semiconductor structure 10 may be applied to a gate-all-around memory device.

The present disclosure provides a semiconductor structure 10 including a space 120 so as to effectively ensure the insulation of the conductive layer 103. Even if the via 122 is not completely aligned with the channel pillar 111 or the over-etching problem occurs during the formation of the via 122, a good ohmic contact between the channel pillar 111 and the via 122 can be ensured and a leakage path between the via 122 and conductive layer 103 can be prevented with such configuration. As such, the electrical performance of the semiconductor structure can be improved. For example, when the channel pillar 111 is not perpendicular to an upper surface of the substrate 101, the etching process for forming the via 122 (e.g. the etching process for forming the opening 118) will not stop at the upper surface of the channel pillar 111 due to the sloping of the channel pillar 111; the etching process will be continued toward the substrate 101, thereby damaging the insulation of the conductive layer 103 in the stacked structure, i.e. an over-etching problem. The present disclosure uses a space 120 to repair the insulation of the conductive layer 103. The embodiments provided by the present disclosure can be integrated into the existing semiconductor manufacturing process. Further, as the semiconductor structure provided by the present disclosure is applied to a 3-dimensional memory device, a leakage path between the word line and the bit line (BL) can be prevented and the insulation of the word line and the bit line can be ensured by arranging the spacer 120 in the semiconductor structure.

In a comparative example, the semiconductor structure does not include a spacer between the dielectric layer and the via; the conductive layer would be exposed in the opening because the over-etching problem occurring during the formation of the opening 118. As a result, the via and/or the barrier layer would be formed on the conductive layer exposed by the opening, the electrical connection cannot be established correctly, and an undesirable leakage path is produced.

It is noted that the structures and methods as described above are provided for illustration. The disclosure is not limited to the configurations and procedures disclosed above. Other embodiments with different configurations of known elements can be applicable, and the exemplified structures could be adjusted and changed based on the actual needs of the practical applications. It is, of course, noted that the configurations of figures are depicted only for demonstration, not for limitation. Thus, it is known by people skilled in the art that the related elements and layers in a semiconductor structure, the shapes or positional relationship of the elements and the procedure details could be adjusted or changed according to the actual requirements and/or manufacturing steps of the practical applications.

While the disclosure has been described by way of example and in terms of the exemplary embodiment(s), it is to be understood that the disclosure is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A semiconductor structure, comprising:
a channel pillar;
a dielectric layer formed above the channel pillar;
a via formed in the dielectric layer and electrically connected to the channel pillar; and
a spacer formed between the dielectric layer and the via.

2. The semiconductor structure according to claim 1, further comprising a stacked structure comprising conductive layers and insulating layers stacked alternately, wherein the dielectric layer is on the stacked structure, the channel pillar passes through the stacked structure along a first direction.

3. The semiconductor structure according to claim 2, wherein the spacer has a thickness between 10-500 angstroms (Å) in a second direction perpendicular to the first direction.

4. The semiconductor structure according to claim 3, wherein the thickness of the spacer in the second direction is 100 Å.

5. The semiconductor structure according to claim 2, wherein a portion of the spacer is formed between the channel pillar and at least one conductive layer of the conductive layers of the stacked structure.

6. The semiconductor structure according to claim 2, wherein a portion of the spacer is formed on a sidewall of the channel pillar.

7. The semiconductor structure according to claim 1, further comprising a barrier layer formed between the via and the spacer.

8. The semiconductor structure according to claim 7, wherein the barrier layer is formed on a sidewall of the via and enclosing the via.

9. The semiconductor structure according to claim 7, wherein the via is electrically connected to the channel pillar through the barrier layer.

10. The semiconductor structure according to claim 1, wherein the spacer comprises oxide.

11. A method for manufacturing a semiconductor structure, comprising:
providing a channel pillar;
forming a dielectric layer above the channel pillar;
forming a spacer in the dielectric layer; and
forming a via in the dielectric layer, wherein the via is electrically connected to the channel pillar, the spacer is between the dielectric layer and the via.

12. The method according to claim 11, further comprising:
providing a stacked structure, wherein the channel pillar passes through the stacked structure along a first direction,
wherein a portion of the spacer is formed between the stacked structure and the channel pillar.

13. The method according to claim 12, wherein the spacer has a thickness between 10-500 angstroms (Å) in a second direction perpendicular to the first direction.

14. The method according to claim 11, wherein the step of forming the spacer in the dielectric layer comprises:
forming an opening through the dielectric layer to expose the channel pillar; and
forming the spacer on a sidewall of the opening.

15. The method according to claim 14, wherein the opening exposes an upper surface of the channel pillar and a sidewall of the channel pillar.

16. The method according to claim 14, wherein the step of forming the spacer in the dielectric layer comprises:
removing a portion of the spacer to expose a pad of the channel pillar.

17. The method according to claim 11, wherein the step of forming the spacer in the dielectric layer comprises:
forming a portion of the spacer on a sidewall of the channel pillar.

18. The method according to claim 11, further comprising:
forming a barrier layer on a sidewall of the spacer, wherein the barrier layer is between the spacer and the via, the via is electrically connected to the channel pillar through the barrier layer.

19. The method according to claim 18, wherein the barrier layer directly contacts the channel pillar.

20. The method according to claim 11, wherein the spacer comprises oxide.
